(19) United States
(12) Patent Application Publication
(10) Pub. No.: US 2009/0178917 A1
(43) Pub. Date: Jul. 16, 2009

(54) METHOD OF SPUTTERING A HIGH-K DIELECTRIC MATERIAL

(75) Inventors: Sunil Wickramanayaka, Tokyo (JP); Naoki Watanabe, Tokyo (JP)

Correspondence Address: BUCHANAN, INGERSOLL & ROONEY PC, POST OFFICE BOX 1404, ALEXANDRIA, VA, 22313-1404, US

(73) Assignee: CANON ANELVA CORPORATION, Kawasaki-shi (JP)

(21) Appl. No.: 12/405,775

(22) Filed: Mar. 17, 2009

Related U.S. Application Data
(63) Continuation of application No. 10/949,335, filed on Sep. 27, 2004.

(30) Foreign Application Priority Data
Sep. 25, 2003 (JP) 2003-332605

(51) Int. Cl. C23C 14/34

(52) U.S. Cl. 204/192.23

(57) ABSTRACT

A multi-cathode ionized physical vapor deposition system includes a reactor in which a wafer holder is arranged at a bottom wall, and at least two angled cathodes opposite a wafer are arranged at a top wall, each of the cathodes is supplied with a RF current via a matching circuit, and a pressure control mechanism including gas inlets and a gas outlet. In the system, an inner pressure of the reactor is controlled to be relatively high pressure by the pressure control mechanism. Thus, the system can form better side-wall and bottom coverage in patterned holes or trenches on the wafer surface using the atoms sputtered on each of the angled multi-cathodes.

### BACKGROUND OF THE INVENTION

1. Field of the Invention

The present invention relates to a multi-cathode ionized physical vapor deposition system, and more particularly, to a plasma assisted sputter deposition system to perform sputtering film deposition using two or more cathodes placed within the same reactor wherein sputtered atoms from targets get ionized within plasma region, accelerate onto a wafer surface by self-bias voltage and deposit on the wafer surface having holes or trenches in sub-micron scale.

2. Description of the Related Art

Magnetron sputtering systems are in wide application to deposit thin films on substrates or wafers used in semiconductor industry. One of the major requirements in depositing the films on the wafers, for example, on Si wafers, is film uniformity. In order to deposit films with a greater uniformity, a multi-cathode sputtering system has been invented and in use. However, this system has severe problems in depositing films on patterned wafers, for example, on surfaces having deep holes or trenches in micron scale. This problem is explained in detail with reference to FIGS. 9-12.

FIG. 9 shows a longitudinal cross sectional view of the conventional multi-cathode sputtering system while FIG. 10 shows an inside view of a top wall on which some cathodes are disposed in a predetermined arrangement manner. A reactor 100 used as a wafer processing chamber is comprised of multi-cathodes (multi-targets) 101a-101d, a wafer holder 102, gas inlets 103 and a gas outlet 104. In FIG. 9, for example, the number of the cathodes is four, and these four cathodes 101a, 101b, 101c and 101d are arranged in an angled state. Each cathode 101a-101d is made of a metal, for example, Al, Ti, Ta etc. that needs to be sputtered and deposited onto a wafer 112 loaded on the wafer holder 102. The cathodes 101a-101d are electrically isolated from the reactor 100 using a dielectric material 105. Generally, on the upper surface of each cathode a plurality of magnets 106 with some specific arrangement has been placed. Further, the magnets 106 arranged on each cathode are preferably rotated around an off-axis or the central axis of the relevant cathode (101a-101d) by a rotating mechanism (not shown). Each cathode (101a-101d) is connected to a DC power source (not shown).

The wafer holder is comprised of a metal electrode 108, a dielectric material 109, a side-wall 110, and a shaft 111. The wafer 112 is horizontally placed on the metal electrode 108 as shown in FIG. 9. The shaft 111 is connected to an electrical motor (not shown) in order to rotate the wafer holder 102 on its central axis 102a.

Plasma is made within the reactor 100 by applying DC electric power to one or several cathodes or targets 101a-101d from the above DC power source (not shown) while maintaining a suitable pressure (relatively high pressure) inside the reactor 100. Owing to the higher negative voltage of the cathode 101a-101d, ions in the plasma are accelerated to the cathode and sputtered. These sputtered atoms then travel through the plasma and deposit on the wafer 112 and other surface areas with which the plasma is in contact. Relatively high pressure means that the pressure facilitates a sufficient number of gas phase collisions between sputtered atoms from the target and Ar ions (or other inert gas) generated by the plasma to ionize the sputtered atoms before they reach the wafer surface.

The sputtered-atom flux coming from each of the angled cathodes (targets) 101a-101d against the horizontal wafer 112 is not radially uniform on the surface of the wafer 112. For example, hypothetical sputtered-atom fluxes from the cathode 101a to the wafer 112 are shown by arrow-like lines 113 in FIG. 11. Further, in FIG. 11, the dotted line 116 shows the amount of the sputtered-atom fluxes given to each spot of the wafer surface. The amount of the atom fluxes depends on the positions of the spots. Since the target arranged on the cathode 101a is in an angled position, the atom fluxes 113 onto the surface of the wafer 112 vary depending to on the distance between the wafer 112 and the target (the cathode 101a). When this distance is short, the wafer gets a higher atom-flux, while the wafer gets a smaller atom-flux when the distance is longer. In order to get a uniform thin film on the surface of the wafer 112, the wafer holder 102 is rotated around its central axis as mentioned above. This results in a uniform film.

The above technique gives extremely uniform films compared to those obtained with sputtering systems where a target and a wafer lie in parallel. The usual film uniformity obtained with the above technique is below ±2% even on 300 mm diameter wafer. If the target and wafer are in parallel, the film uniformity depends on the plasma uniformity close to the target, pressure, and the magnet configuration above the target. Even if all those parameters are optimized, it is extremely difficult to obtain film uniformity about ±5% over a 300 mm diameter wafer.

The sputtered atoms from the cathode are in a neutral state. Since very low-pressures, for example, pressures below 10 mTorr (1.3 Pa), are employed for the sputtering, the sputtered atoms are subjected to only a few collisions within the gas phase before depositing on the wafer surface. Even though there are Ar+ ions and Ar excited state atoms within the plasma that can ionize the sputtered atoms by collisions, the sputtered atoms are less likely to be ionized due to the lower number of gas-phase collisions. Accordingly, almost all the deposition on the wafer surface is occurred by neutral atoms.

Film deposition by the neutral atoms is useful if the film is deposited on a planar surface. However, if there are holes or trenches, especially in sub-micron scale, the film deposition by the neutral atoms has limits. This is explained with reference to FIGS. 11 and 12. Since the sputtered atoms are coming with an angle to the wafer surface, most of the films 114 deposited in holes or trenches 115 happens on the walls that face the atom flux as schematically shown in FIG. 11. This results in an asymmetric film deposition on the side-walls of the holes or trenches 115 as shown in FIG. 12. Further, if the diameter of the holes or the width of the trenches is in sub-micron scale with a higher aspect ratio, the films get thinner towards the bottom of the holes or trenches 115. Because, only a few atoms reach the bottoms of the holes or trenches 115. This causes discontinuous film on the side-walls of the holes or trenches. Therefore, application of the above-explained sputtering system for patterned wafers is limited.

Japanese Patent Publication (A) No. 2002-167661 or Japanese Patent Publication (A) No. 2002-296413 discloses one example of the multi-cathodes sputtering wafer processing chamber. The multi-cathodes sputtering wafer processing chamber has four cathodes angled in a ceiling portion. Magnetic multi-films to be required are deposited on the wafer loaded on the wafer holder by sputtering each of the four cathodes suitably.

As other related arts, there are some patent documents of US2001/0004047, JP-A-10-204634, JP-A-2003-318165, JP-A-2001-220671, JP-A-156374 and JP-A-2000-353667. In some of these patent documents, the examples of the inner pressure in the reactor are disclosed and discussed.

It is required to deposit films uniformly on the whole inside surface of the holes or trenches made on the wafer surface using the atoms which are sputtered from the angled targets or cathodes and ionized within the plasma. Further, when the wafer has patterned deep holes or trenches with a higher aspect ratio, films with good coverage from the opening entrance to the bottom are deposited using the sputtered and ionized atoms.

### SUMMARY

An object of the present invention is to provide a multi-cathode ionized physical vapor deposition system capable of forming better side-wall and bottom coverage in patterned holes or trenches on the wafer surface using the (neutral) and ionized atoms sputtered on each of the angled multi-cathodes.

A multi-cathode sputter ionized physical vapor deposition system in accordance with the present invention is configured as follows in order to attain the above-mentioned object.

A first multi-cathode ionized physical vapor deposition system is comprised of a reactor in which a wafer holder is arranged at a bottom wall so as to be rotated around its central axis, and at least two angled cathodes against a wafer placed on the wafer holder are arranged at a top wall, each of the cathodes is supplied with a RF current via a matching circuit from a RF generator, and a pressure control mechanism including gas inlets and a gas outlet. In the system, an inner pressure of the reactor is controlled to be a relatively high pressure by the pressure control mechanism.

In accordance with the above system, the plasma within the reactor is preferably generated under a pressure higher than 5 Pa. This condition ionizes the sputtered atoms and deposition is mainly occurred by the accelerated ions to the wafer surface.

In the above multi-cathode ionized physical vapor deposition system, preferably, the system comprises a central cathode parallel to the wafer at a center of the top wall.

In the above multi-cathode ionized physical vapor deposition system, preferably, the system comprises DC sources respectively supplying the cathodes with a DC voltage.

In the above multi-cathode ionized physical vapor deposition system, preferably, one or more of the cathodes are supplied DC current in addition to RF current.

In the above multi-cathode ionized physical vapor deposition system, preferably, a wafer loaded on the wafer holder is biased.

A second multi-cathode ionized physical vapor deposition system is comprised of a reactor in which a wafer holder is arranged at a bottom wall so as to be rotated around its central axis, and at least two angled cathodes against a wafer placed on the wafer holder are arranged at a top wall, each of the cathodes is supplied with a DC voltage from a DC source, a pressure control mechanism including gas inlets and a gas outlet, and a central cathode parallel to the wafer at a center of the top wall. In the above system, an inner pressure of the reactor is controlled to be a relatively low pressure by the pressure control mechanism, wherein a relatively low pressure means a pressure such that the mean free path of gas atoms is less than or equal to the distance between the cathode and the wafer.

In the above system, the inner pressure of the reactor is 0.1 Pa at most.

In the above systems, the target material of either one of the cathodes is preferably high-dielectric constant material such as HfO₂ or HfSiON.

Further, In the above systems, target materials of cathodes are dielectric materials or metals such as HfO₂, Si₃N₄, Al₂O₃ and Hf, which are reacting together to form another dielectric material on the wafer during co-sputtering, where two or more cathodes are given RF or DC voltage at the same time.

In the above systems, each cathode has a magnet arrangement on its outside surface to generate magnetic flux that penetrates a cathode surface and reaches the inside of the reactor.

In accordance with multi-cathode ionized physical vapor deposition system of the present invention can deposit films the wafer with patterned holes or trenches of higher aspect ratio in the state of better side-wall and bottom coverage.

### BRIEF DESCRIPTION OF THE DRAWINGS

These and other objects and feature of the present invention will become clearer from the following description of the preferred embodiments given with reference to the attached drawings, wherein:

FIG. 1 is a longitudinal cross sectional diagram of the system of the first embodiment of the present invention;

FIG. 2 is a bottom view of cathode arrangement in a reactor shown in FIG. 1;

FIG. 3 is an explanation view showing a path of a sputtered atom from a cathode to wafer surface;

FIG. 4 is a cross sectional view showing a hypothetical side and bottom coverage in a hole or trench on the wafer surface;

FIG. 5 is a longitudinal cross sectional diagram of the system of the second embodiment of the present invention;

FIG. 6 is a bottom view of cathode arrangement in a reactor shown in FIG. 5;

FIG. 7 is a longitudinal cross sectional diagram of the system of the third embodiment of the present invention;

FIG. 8 is a longitudinal cross sectional diagram of the system of the fourth embodiment of the present invention;

FIG. 9 is a longitudinal cross sectional diagram of a conventional system;

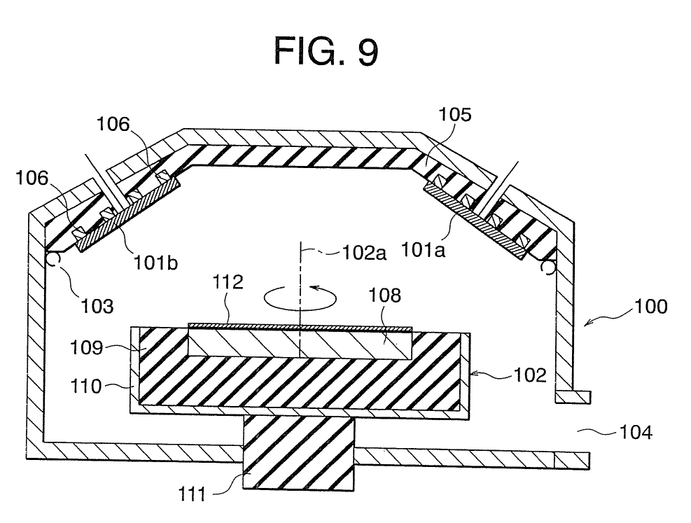

FIG. 10 is a bottom view of cathode arrangement in a reactor shown in FIG. 9;

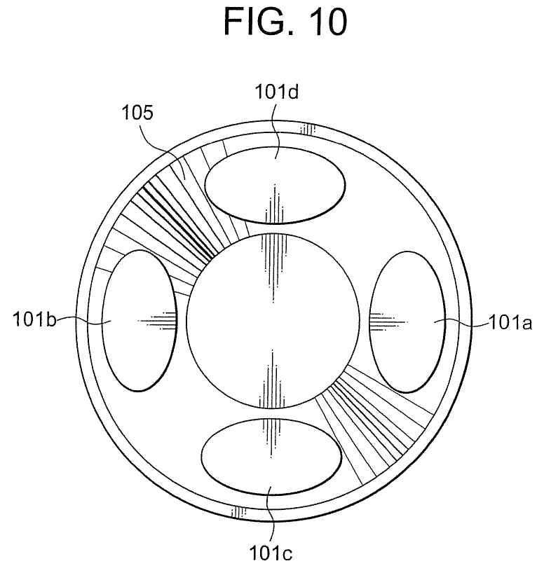

FIG. 11 is an explanation view showing the direction of sputtered-atom flux; and

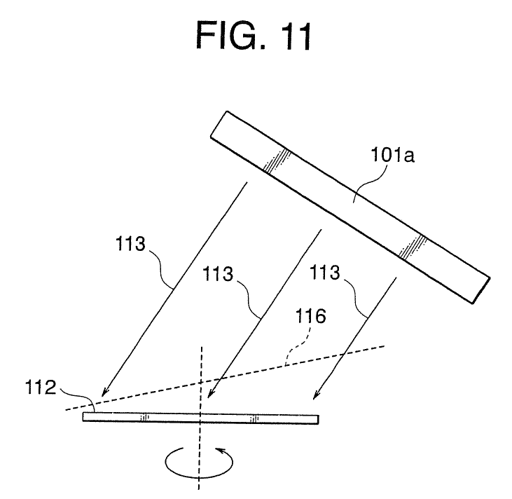

FIG. 12 is a cross sectional view of a hole or trench after the film deposition with the reactor shown in FIG. 9.

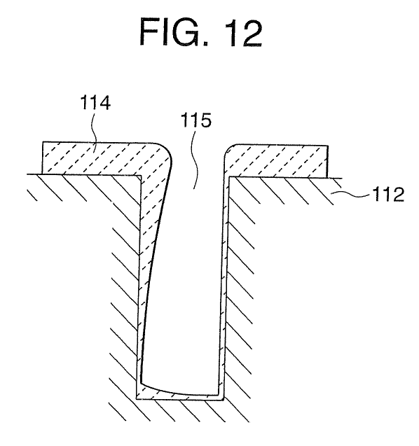

### DESCRIPTION OF THE PREFERRED EMBODIMENTS

Hereinafter, preferred embodiments will be explained according to the attached drawings. Through the explanation of the embodiments, the details of the present invention will be clarified.

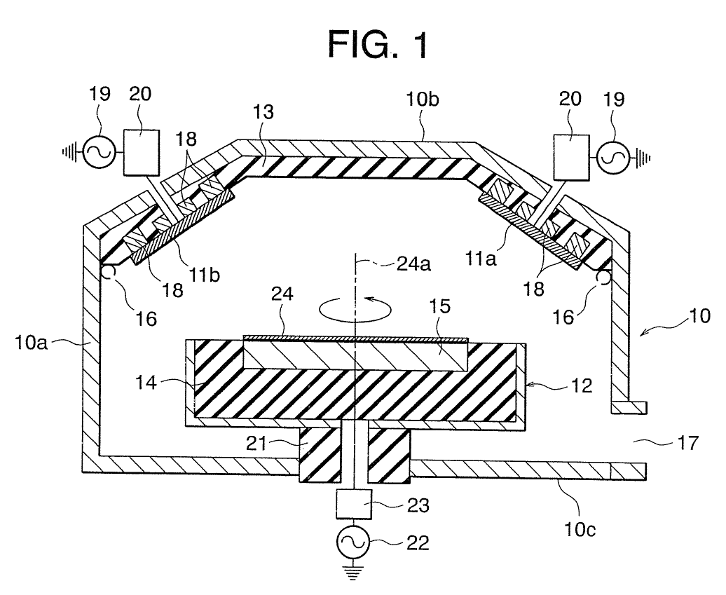

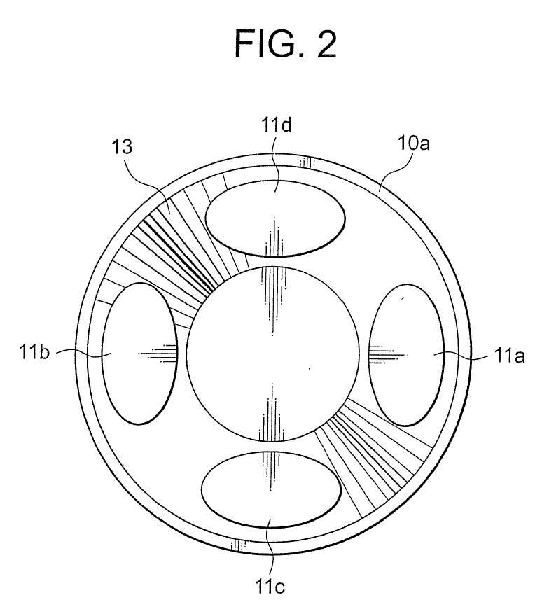

In accordance with FIGS. 1-4 the first embodiment of the present invention is explained. A longitudinal cross sectional diagram of a multi-cathode sputter deposition reactor 10 is shown in FIG. 1. The bottom view of multi-cathode arrangement is shown in FIG. 2. The reactor 10 is formed by a side-wall 10a, top wall 10b and bottom wall 10c, and has an airtight structure. Further, the reactor 10 is provided with two or several cathodes (four cathodes 11a, 11b, 11c, 11d, for example) used as a target, wafer holder 12, lower electrode 15 which is an integrated part of the wafer holder 12, and insulating materials 13 and 14 to electrically isolate the cathodes and the lower electrode 15 from the rest of the reactor 10. The number of the cathodes is preferably four. The four cathodes 11a-11d are fixed on the inside surface of a top wall of the reactor 10 in an angled state through the insulating material 13. The four cathodes 11a-11d are arranged along a circled outer edge of the upper wall in an equivalent interval.

In the inside of the reactor 10, there is a plurality of gas inlets 16 to introduce a gas (Ar etc.) or a mixture of gases into the reactor 10 and a gas outlet 17. The gas inlets 16 are connected to a gas supply device (not shown) and the gas outlet 17 is connected to a vacuum pump (not shown). Thus, the reactor 10 has a pressure control mechanism including the gas inlets 16 and the gas outlet 17 etc. in order to control the inner pressure of the reactor to be a relatively high pressure. A relatively high pressure is a pressure high enough to ionize sputtered atoms by gas phase collisions before the atoms reach the wafer surface.

The four cathodes 11a-11d are arranged at an angle to a central portion of the top wall 10b. The central portion of the top wall 10b is parallel to the lower electrode 15. The diameter of the cathode is not critical and selected according to the other dimensions of the reactor 10. For example, if the reactor 10 is designed to process wafers with diameter of 300 mm, the diameter of the cathode 11a-11d may lie in the range of 200 mm to 400 mm.

The cathode material or target material is usually a metal, such as Al, Ti, Ta, Mn etc. Further, one can use even semiconductors or dielectric materials for the target. Targets made by the dielectric materials are, for example, SiO₂, SiN or high-k dielectric materials such as HfON or HfSiON. All the cathodes 11a-11d may be made of the same material or different materials.

There may or may not be any magnet arrangement on the outer surface of each of cathodes 11a-11d. In FIG. 1, a plurality of separate magnets 18 arranged on the outer surface of each cathode is shown. Usually, these magnet arrangements may be rotated on off-axis or on the central axis of the cathode. There is no any specific arrangement for the magnets 18. The configuration of the magnet arrangement can be selected by considering the target utilization efficiency and film uniformity.

Each cathode (11a-11d) is connected to a RF generator 19 via a matching circuit 20. The frequency of the RF generator 19 is not critical and can be in the range of 10 MHz to 300 MHz. Further, all of the cathodes 11a-11d may be given a RF current operating at the same frequency or different frequencies.

The wafer holder 12 is arranged on a bottom wall of the reactor 10 and placed at least 50 mm below the closest cathode. The wafer holder 12 is fixed to a shaft 21 that can be rotated with the use of an electric motor (not shown). The lower electrode 15 is usually made of a metal such as Al, and is connected to a RF generator 22 via a matching circuit 23. However, application of the RF power from the RF generator 22 to the lower electrode 15 is not essential for the purpose of this invention. If a RF current is applied to the lower electrode 15, the frequency of the RF current is not critical and lies in the range of 100 kHz to 50 MHz. A wafer 24 on which films are deposited is loaded on the lower electrode 15.

Next, an operation of the above-mentioned multi-cathode sputter deposition system is explained. First, a process gas, usually Ar, is fed into the reactor 10 through the gas inlets 16. The inner pressure of the reactor 10 is maintained to be higher than 5 Pa. This inner pressure of the reactor 10 is relatively high. In the reactor 10 plasma is generated by applying the RF current to a selected cathode or some selected cathodes. The RF current is usually applied to the selected cathode that needs to be sputtered. Accordingly, if two different materials are needed to be sputtered simultaneously, RF currents are applied to both cathodes at the same time.

When the plasma is generated by capacitively coupling of the RF power, a negative self-bias voltage is generated on the selected cathodes. Depending on the applied RF power, frequency of the RF current, and pressure, the value of self-bias voltage changes. This negative self-bias voltage generates a DC electric field on the surface of cathode (11a-11d) that accelerates ions in the plasma, for example, Ar+ ions. Bombardment of high-energy ions on the cathode surface causes sputtering of cathode material or target material into the plasma.

Sputtered atoms emitted from the cathode or target are in a neutral state. Owing to the higher pressure employed, these sputtered atoms are subjected to a large number of collisions before depositing on the wafer 24 or another surfaces within the reactor 10. The collisions with Ar+ ions and Ar* excited states results in ionization of the sputtered atoms. Accordingly, a fraction of the sputtered atoms ionize within the gas phase. The ionization fraction of the sputtered atoms depends on the distance between the cathode (11a-11d) and the wafer 24, pressure, and plasma density within the reactor 10.

If the lower electrode 15 is given the RF current, a negative self-bias voltage is generated on the surface of the wafer 24. This negative self-bias voltage generates a DC electric field that accelerates the ionized sputtered-atoms to the wafer surface.

If the lower electrode 15 is not given the RF current and is also not connected to the ground, the wafer 24 is on an electrically floating state. In this state wafer potential is given as floating potential (Vf). This floating potential (Vf) is always lower than plasma potential (Vp). Therefore, there is a potential difference defined by Vp−Vf. This potential difference generates an electric field towards the wafer 24. This electric field accelerates the ionized sputtered atoms in the plasma to the wafer surface. Therefore, the ionized sputtered atoms come almost normal to the wafer surface.

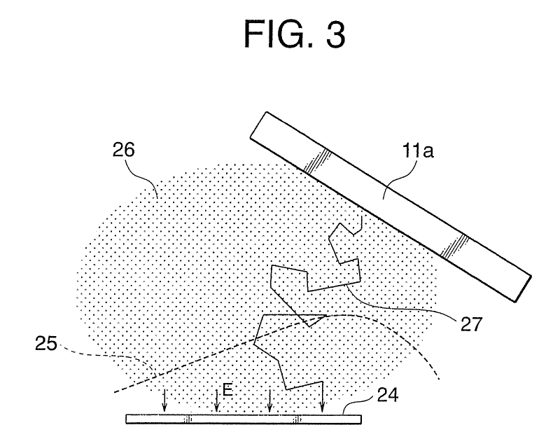

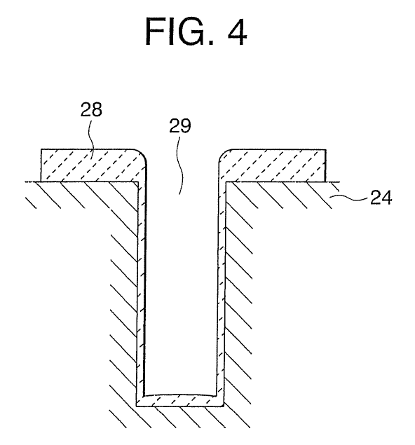

The above-mentioned phenomenon is schematically shown in FIG. 3. In FIG. 3, a dotted line 25 near the surface of wafer 24 shows a radial profile of atoms or ions flux from the cathode 11a and region 26 shows the plasma. Further, the above electric field (E) is generated towards the surface of the wafer 24 in the basis of the potential difference (Vp−Vf), as shown by arrows. In the plasma 26, the sputtered atom emitted from the cathode 11a moves as shown by a path 27. In accordance with the moving path 27 of the sputtered atom, the ionized sputtered atom is accelerated toward the wafer surface and comes almost or preferably normal to the wafer surface. Thus, the operation results in a uniform side-wall coverage and better bottom coverage 28 in holes or trenches 29 on the wafer 24 as shown in FIG. 4.

In the above, since there is a certain potential difference between the plasma and the wafer, the ionized atoms are accelerated to the wafer surface. The atoms sputtered from the cathode 11a make angled fluxes and are ionized in the plasma. In this case, the inner pressure must be relatively high in order to change the atoms into the ions in the plasma. The above-mentioned necessary potential difference is naturally generated, or produced by applying a RF power to a wafer holder.

The ionized or neutral atom flux, however, is not uniform on the wafer surface. It is highly asymmetric pattern as shown by the line 25 in FIG. 3. The line 25 represents the atom or ionized atom flux density with respect to the cathode 11a. However, as the wafer 24 is rotated around its central axis 24a as shown in FIG. 1, the resulted film shows a good uniformity.

Next, instead of the RF generator 19 mentioned above, one can use a DC source to supply a DC voltage to the cathodes 11a-11d. The purpose of applying the DC voltage to the cathodes is to increase the sputter rate of the cathode or target by increasing the cathodes' negative voltage. In addition, the use of the RF generator or the DC source may be determined in dependence on materials of the cathodes.

In accordance with the first embodiment, its effect is to give better side-wall and bottom coverage in the holes or trenches on the surface of the wafer.

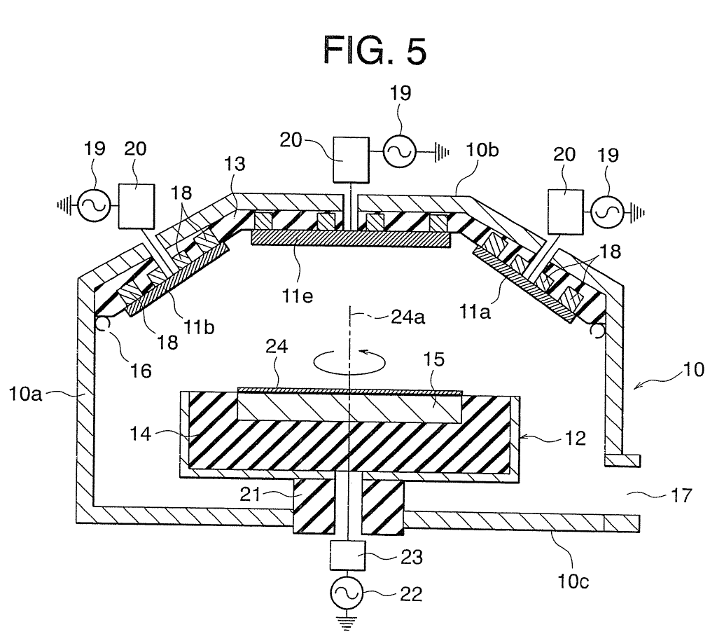

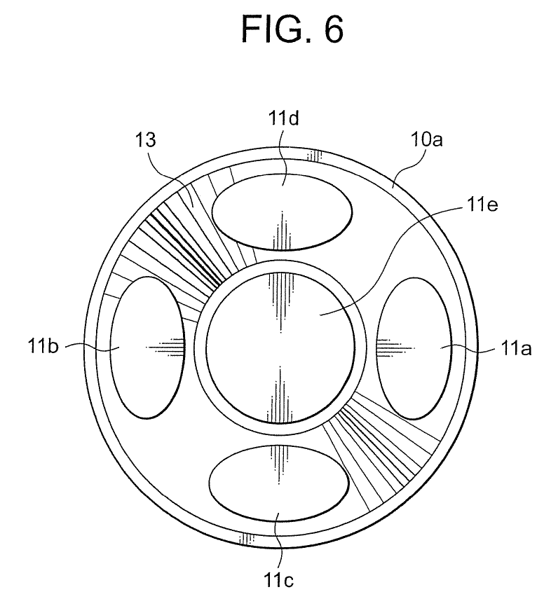

In accordance with FIGS. 5 and 6, the second embodiment of the present invention is explained. In the second embodiment, FIGS. 5 and 6 correspond to FIGS. 1 and 2, respectively. Compared with a multi-cathode sputter deposition system of the first embodiment, in the system of the second embodiment, a central cathode 11e parallel to the lower electrode 15 is added. The central cathode 11e substantially has the same structure and function as the above-mentioned angled cathodes 11a-11d. The diameter or size of the central cathode is not necessarily the same as that of the angled cathodes. Except the above addition of the central cathode 11e and the related configuration, all the other hardware are the same as that explained in the first embodiment. Therefore, in FIGS. 5 and 6, components substantially identical to those explained in the first embodiment are designated with the same reference numbers. The method of operation and the merits obtained in the second embodiment are also the same as that described in the first embodiment.

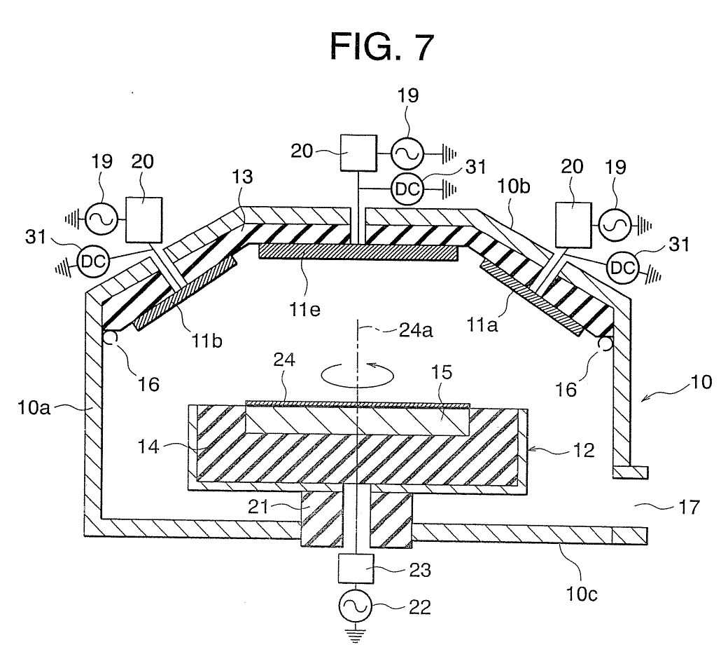

In accordance with FIG. 7, the third embodiment of the present invention is explained. FIG. 7 corresponds to FIG. 5 of the second embodiment. Here, the only difference, as compared with the second embodiment, is that each cathode 11a-11e is connected to a DC power supply 31 in addition to the RF power supply 19. During the operation, therefore, one or all cathodes may be given a DC power in addition to the RF power. Application of additional DC power to a cathode causes an increase of its negative voltage. This increases the sputter rate of the cathodes 11a-11e. Except the above addition of the DC power supply 31, all the other hardware is the same as that explained in the first or second embodiment. Therefore, in FIG. 7, components substantially identical to those explained in the first or second embodiment are designated with the same reference numbers. The method of operation and the merits obtained are also the same as that described in the first or the second embodiment.

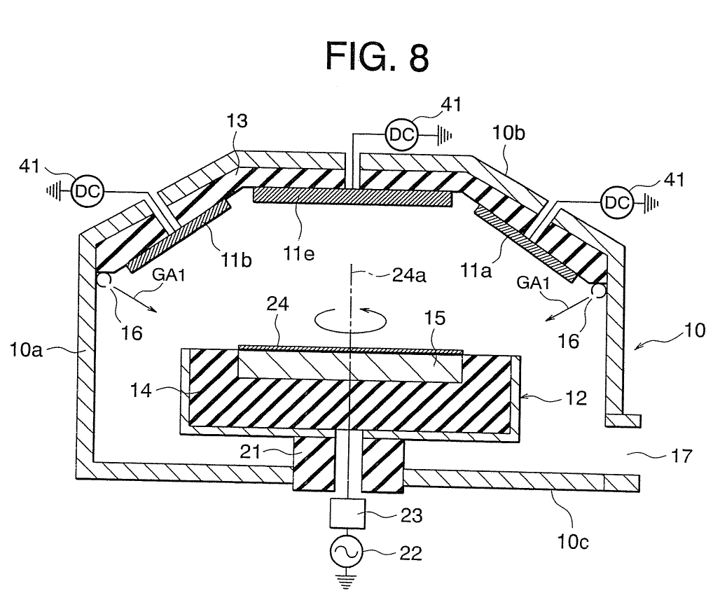

Next, the fourth embodiment of the present invention is explained in accordance with FIG. 8. The hardware configuration of the fourth embodiment may be any of the configurations explained in the above embodiments. The configuration shown in FIG. 8 is a modification of the third embodiment. In the fourth embodiment, there are two differences as compared with the configuration of the third embodiment. One is that the operational pressure within the reactor 10 is lowered considerably to a lower level by controlling the gas flow (GA1) from the gas inlets 16 into the reactor 10. And another is that only the DC power source 41 is used as a power source for the cathodes 11a-11e or target.

In FIG. 8, as to other components except the DC power source 41, the components substantially identical to those explained in the above-mentioned embodiments are designated with the same reference numbers.

First, slightly a higher pressure, around 0.1 Pa, is maintained during the plasma ignition stage. Plasma is ignited using only the DC electrical power. After the plasma is ignited, the gas flow is reduced causing a decrease of pressure within the reactor 10. Since the plasma is generated during the pressure decreasing stage, sputtered atoms behaves as gaseous atoms and get ionized by accelerating electrons, which is essential to maintain the plasma. This process is usually called as “self-ionization”. These ionized atoms then accelerate towards grounded surface. By placing the wafer in an electrically ground state, those ionized atoms can be directed onto the wafer surface.

As the electrical field on the wafer is perpendicular to its surface, ionized atom deposition occurs exactly as explained in the first embodiment. Accordingly, the same results or merits explained in the first embodiment can be obtained.

The present invention explained by the above various embodiments is used for forming better side-wall and bottom coverage in patterned deep holes or trenches on the wafer surface with the use of the neutral atoms sputtered on each of the angled multi-cathodes in the PVD sputtering system.

The present disclosure relates to subject matter contained in Japanese Patent Application No. 2003-332605, filed on Sep. 25, 2003, the disclosure of which is expressly incorporated herein by reference in its entirely.

Although only preferred embodiments are specifically illustrated and described herein, it will be appreciated that many modifications and variations of the present invention are possible in light of the above teachings and within the purview of the appended claims without departing from the spirit and intended scope of the invention.

What is claimed is:

1. A method of sputtering comprising:
controlling a reactor pressure to a pressure higher than 5 Pa,
putting a wafer on a wafer holder in said reactor and rotating said wafer,
arranging a target and cathode having a high-k dielectric material with an angle to said wafer,
applying a first RF current to said cathode, and
applying a second RF current to a lower electrode provided in said wafer holder, whereby a negative bias potential with respect to a plasma potential is applied to said lower electrode.

2. A method of sputtering comprising:
controlling a reactor pressure to a pressure higher than 5 Pa,
putting a wafer on a wafer holder in said reactor and rotating said wafer,
arranging a target and cathode having a high-k dielectric material with an angle to said wafer,
applying a first RF current to said cathode,
ionizing sputtered atoms emitted from said cathode, and
placing a lower electrode provided in said wafer holder in a state of being not grounded and not connected with an RF current such that the wafer is placed in a potentially floating state, whereby a negative bias with respect to a plasma potential is applied to said lower electrode.

3. A method of sputtering comprising:
controlling a reactor pressure to a pressure higher than 5 Pa,
putting a wafer on a wafer holder in said reactor and rotating said wafer,
arranging a plurality of targets and cathodes having a high-k dielectric material with an angle to said wafer,
applying a first RF current to said cathodes,
generating a negative self-bias voltage on a selected one of said cathodes when a plasma is produced by a capacitive coupling of an RF power of a first RF generator,
ionizing sputtered atoms emitted from said cathode, and
applying a second RF current to a lower electrode provided in said wafer holder, whereby a negative bias potential with respect to a plasma potential is applied to said lower electrode.

4. A method of sputtering comprising:
controlling a reactor pressure to a pressure higher than 5 Pa,
putting a wafer on a wafer holder in said reactor and rotating said wafer,
arranging a plurality of targets and cathodes having a high-k dielectric material with an angle to said wafer,
applying a first RF current to said cathodes,
generating a negative self-bias voltage on a selected one of said cathodes when a plasma is produced by a capacitive coupling of an RF power of a first RF generator,
ionizing sputtered atoms emitted from said cathode, and
placing a lower electrode provided in said wafer holder in a state of being not grounded and not connected with an RF current such that the wafer is placed in a potentially floating state, whereby a negative bias with respect to a plasma potential is applied to said lower electrode.

5. The method of sputtering as claimed in claim 1, wherein said cathode is further supplied with a DC current in addition to said first RF current.

6. The method of sputtering as claimed in claim 1, wherein said high-k dielectric material is HfSiON.

7. The method of sputtering as claimed in claim 2, wherein said cathode is further supplied with a DC current in addition to said first RF current.

8. The method of sputtering as claimed in claim 3, wherein said cathode is further supplied with a DC current in addition to said first RF current.

9. The method of sputtering as claimed in claim 4, wherein said cathode is further supplied with a DC current in addition to said first RF current.

10. The method of sputtering as claimed in claim 2, wherein said high-k dielectric material is HfSiON.

11. The method of sputtering as claimed in claim 3, wherein said high-k dielectric material is HfSiON.

12. The method of sputtering as claimed in claim 4, wherein said high-k dielectric material is HfSiON.
